(19) United States
(12) Patent Application Publication
(10) Pub. No.: US 2024/0272281 A1
(43) Pub. Date: Aug. 15, 2024

(54) OPTICAL SENSOR ARRANGEMENT

(71) Applicant: ams-OSRAM International GmbH, Regensburg (DE)

(72) Inventors: Martin HETZL, Painten (DE); Reiner WINDISCH, Pettendorf (DE); Jens EBBECKE, Rohr in Niederbayern (DE)

(73) Assignee: ams-OSRAM International GmbH, Regensburg (DE)

(21) Appl. No.: 18/682,042

(22) PCT Filed: Aug. 5, 2022
(86) PCT No.: PCT/EP2022/072092

§ 371 Date: Feb. 7, 2024

(30) Foreign Application Priority Data
Aug. 9, 2021 (DE) 10 2021 120 638.3

(51) Int. Cl. G01S 7/481; G01S 7/484; G01S 7/4865; G01S 17/10; H01S 5/10; H01S 5/34

(52) U.S. Cl. CPC G01S 7/4814; G01S 7/484; G01S 7/4865; H01S 5/1092; G01S 17/10; H01S 5/34

(57) ABSTRACT

An optical sensor arrangement, for example for a LiDAR system, includes an emitter unit and a receiver unit. The emitter unit includes a semiconductor laser configured to emit coherent electromagnetic radiation having at least two wavelengths. Furthermore, the emitter unit is configured to direct the emitted electromagnetic radiation at a remote target, the receiver unit including at least one optical sensor configured to selectively detect electromagnetic radiation depending on the at least two wavelengths. The receiver unit is arranged relative to the emitter unit and configured such that electromagnetic radiation scattered or reflected by the remote target is detectable on the optical sensor.

### CROSS-REFERENCE TO RELATED APPLICATIONS

The present application is a national stage entry from International Application No. PCT/EP2022/072092, filed on Aug. 5, 2022, published as International Publication No. WO 2023/016939 Al on Feb. 16, 2023, and claims priority to German Patent Application No. 10 2021 120 638.3, filed Aug. 9, 2021, the disclosures of all of which are hereby incorporated by reference in their entireties.

### FIELD

The following description relates to an optical sensor arrangement, for example for a LiDAR system.

### BACKGROUND

Optical sensors are increasingly being designed as modules with a light source and an optical receiver. For example, “light detection and ranging” (LiDAR for short) is a technology that can be used to measure distances to distant targets. Typically, a LiDAR system comprises a light source and an optical receiver. The light source can be a laser, for example, which emits light having a specific operating wavelength. The operating wavelength of a LiDAR system can, for example, be in the infrared, visible or ultraviolet range of the electromagnetic spectrum. The light source emits light in the direction of a target, which can then scatter or reflect the light. Part of the scattered or reflected light can be received again at the receiver. The distance to the target can be determined from sensor signals by evaluating one or more characterstics associated with the reflected light. These characteristics can vary depending on the type of LiDAR used. For example, the system can determine the distance to the target based on the time-of-flight (ToF for short) of a returned light pulse.

ToF-LiDAR, such as scanning systems, are limited in their repetition rate or frame rate, i.e. the scanning speed, by the speed of light. With direct ToF-LiDAR systems in particular, in each case an emitted laser pulse is reflected by a target and detected by the detector before a next laser pulse can be emitted at a different angular position. The reason for this is that there should be unambiguity between the emitted pulses and the pulse responses or beam directions. For a maximum distance d and speed of light c, the minimum time between two pulses is dt=2*d/c. This means that at a distance of 150 m, the light requires approx. 1 μs for travelling to and returning from the target and therefore the sampling rate for this example cannot be higher than 1 MHz.

One way of overcoming this limit is to use several lasers with different wavelengths. These wavelengths must be separated far enough from each other so that each wavelength can be detected by a separate detector. This means that a different laser and a different detector are required for each wavelength.

For the detector, this is realized by specific wavelength bandpass filters that are wide enough to take into account any deviations from the desired wavelength, for example due to temperature or current, but also small enough not to detect the other wavelengths.

For two wavelengths, this reduces the minimum time between two pulses to dt=d/c, for three wavelengths to dt=2*d/(3*c), etc. For the emitters, each laser must be produced with a different emission wavelength, which means completely separate production cycles. These are complex and expensive. Furthermore, the lasers as optical components must be aligned in relation to the other lasers and optical components in the LiDAR system, for example to adapt the beam guidance optics. This is also difficult and expensive. Finally, separate anode and cathode contacts are required for the individual lasers, which entails a complex driver geometry and large dimensions and therefore high manufacturing costs.

The object of this specification is to propose an optical sensor arrangement that enables improved measurement with compact dimensions and low-cost production.

This object is achieved by the subject-matter of the independent claim. Further developments and embodiments are described in the dependent claims and will become apparent from the following description and the drawings.

### SUMMARY

The following is based on the premise that each feature described in relation to any embodiment may be used alone or in combination with other features described below and may also be used in combination with one or more features of any other embodiment or any combination of any other embodiment, unless described as an alternative. Furthermore, equivalents and modifications not described below may also be used without departing from the scope of the proposed optoelectronic component and method of producing an optoelectronic component defined in the accompanying claims.

An improved concept in the field of optical sensors, for example optical sensors for LiDAR systems, is presented below. One aspect is to propose an optical sensor arrangement comprising a semiconductor laser as a light source that can emit electromagnetic radiation having two or more wavelengths. Different LiDAR systems, such as scanning LiDAR systems, represent an application example. Instead of providing a corresponding semiconductor laser for the respective wavelength, a single semiconductor laser (or laser bar) with different channels corresponding to different emission wavelengths can be used.

In one application example, a separation of wavelengths for each emitter on the same chip can be achieved during frontend processing by quantum well intermixing (QWI for short) . For impurity-free QWI, for example, a layer of Si0₂ is deposited on an epitaxially grown surface of the laser. If the temperature is raised high enough, the resulting strain causes Ga atoms to leave the surface layer and penetrate into the dielectric layer. The remaining point defects diffuse into the semiconductor and lead to an exchange of positions of the atoms past which the point defects diffuse. This material exchange causes the atoms of the quantum wells (QWs for short) and the barriers to intermix, which leads to an increase in the band gap and thus to a change in the emission wavelength. It was found that the degree of intermixing can be controlled by varying the thickness of the Si02 layer, making it possible to process lasers with different wavelengths on one chip.

According to at least one embodiment, an optical sensor arrangement comprises in particular an emitter unit and a receiver unit.

The emitter unit comprises a semiconductor laser configured to emit coherent electromagnetic radiation having at least two wavelengths. The emitter unit is further configured to direct the emitted electromagnetic radiation towards a distant target.

The receiver unit comprises at least one optical sensor configured to selectively detect electromagnetic radiation depending on the at least two wavelengths. The receiver unit is arranged relative to the emitter unit and configured such that electromagnetic radiation scattered and reflected by the distant target is detectable on the optical sensor.

The optical sensor arrangement can use several wavelengths, the semiconductor laser being realized on the same chip. This means, for example, that only one laser production cycle is required. Individual cathodes can be provided for each laser channel, but the channels can be driven via a common anode.

In a sense, the semiconductor laser represents a single light source. This means that optical alignment between several light sources, such as several lasers, is not necessary. This not only simplifies the manufacture of the optical sensor arrangement, but also simplifies alignment. This makes the optical sensor arrangement more robust, compact and cost-effective. LiDAR systems can benefit from the use of two different wavelengths to spectrally separate a fast pulse sequence. This reduces the minimum time between two pulses so that a better temporal resolution can be achieved.

Here and in the following, light or electromagnetic radiation can equally mean electromagnetic radiation of at least one wavelength or a wavelength range from the infrared to the ultraviolet. In particular, the two (or more) wavelengths that can be emitted by the semiconductor can originate from the ultraviolet, infrared and/or visible spectrum, for example a red to blue wavelength range with one or more wavelengths between approximately 350 nm and approximately 700 nm or approximately the near infrared.

The coherent electromagnetic radiation can be characterized in particular by a spectrum with a spectral width of less than 10 nm and preferably less than 5 nm and have a large coherence length. This may mean that the coherent electromagnetic radiation has a coherence length of an order of magnitude of meters up to an order of magnitude of one hundred meters or more. As a result, it may be possible for the coherent electromagnetic radiation to be collimated and/or focused into a beam with low divergence and a small beam cross-section. For this purpose, a radiation outcoupling surface, for example of a semiconductor layer sequence of the semiconductor laser, can be followed by a collimating or focusing optics unit such as an anamorphic lens, for example a cylindrical lens, by which the coherent electromagnetic radiation can be collimated and/or focused into a beam that can have beam properties similar to an ideal Gaussian beam. The coherent electromagnetic radiation can be generated in an active region during operation of the semiconductor laser by stimulated emission with a fixed phase relationship and a narrowly limited solid angle range.

In a sense, the semiconductor laser represents a single component with different laser ranges. The component is defined, for example, by a common structure in a common semiconductor body (such as a semiconductor layer sequence), which is configured to generate several wavelengths. The rest of this description is also based on this concept. Alternatively, the component can also be regarded as a component with several lasers, because the laser regions or the structures that emit the coherent electromagnetic radiation of at least two wavelengths represent separate lasers, so to speak.

According to at least one embodiment, the semiconductor laser comprises a semiconductor layer sequence. The semiconductor layer sequence comprises at least a first active layer and a second active layer. The first active layer comprises one or more first active regions, each of which is formed as a quantum well structure. The second active layer comprises one or more second active regions, each of which is formed as a quantum well structure.

During operation, the quantum well structure can generate coherent electromagnetic radiation. The quantum well structure of the first active layer is configured to emit coherent electromagnetic radiation of a first wavelength. The quantum well structure of the second active layer is configured to emit coherent electromagnetic radiation of a second wavelength.

Quantum well structure means in particular that the active region can comprise one or more quantum wells. The quantum well structures can be implemented in a common semiconductor layer sequence and thus on a single chip. The semiconductor laser can be understood as a quantum well laser. Such a quantum well laser is in particular a laser diode in which the active region of the component is dimensioned such that quantum confinement takes place. Quantum well lasers are formed, for example, from compound semiconductor materials that can emit light efficiently. The wavelength of the light emitted by a quantum well laser can be determined by the band gap of the material and the width of the active region. For example, a quantum well structure having several quantum wells (multi-quantum well) offers a laser structure with a very thin (approx. 10 nm thick) layer of bulk semiconductor material, which lies, for example, between barrier regions of a semiconductor material with a higher band gap. This restricts the movement of the electrons and holes and quantizes the kinetic energies.

According to at least one embodiment, the semiconductor layer sequence comprises one or more further active layers comprising active regions formed as a quantum well structure. The quantum well structure, or the quantum well structures, are each configured to emit coherent electromagnetic radiation of a further wavelength.

The semiconductor layer sequence can comprise several active layers and corresponding quantum well structures as active regions. To a certain extent, this is only limited by the respective application of the optical sensor arrangement. For example, LiDAR systems can benefit from the use of two different wavelengths in order to be able to spectrally separate a fast pulse sequence. Additional wavelengths further reduce the minimum time between two pulses so that a better temporal resolution can be achieved. Other applications can also benefit from a multi-color laser source, for example to take advantage of multiple measurements at different wavelengths.

According to at least one embodiment, the further wavelengths are different from the first and second wavelengths. Alternatively, or in addition, one or more of the other wavelengths may correspond to a further wavelength, for example the first and second wavelengths.

The further wavelengths can be used for spectral separation on the optical sensor side. In LiDAR systems, for example, the minimum time between successive pulses can be reduced if the pulses are emitted at different wavelengths. However, it can also be useful to emit some wavelengths through two or more active regions. This can increase the intensity of the emission.

According to at least one embodiment, one or more of the active layers comprise an intermixed quantum well (QWI) structure as the quantum well structure.

QWI is an integration technology in which properties of the quantum well structure can be modified after growth. For example, the process can combine active and passive components on the same chip. Intermixing of the potential wells and barriers of quantum well structures generally leads to an increase in the band gap and is accompanied by changes in the refractive index. A number of techniques based on impurity diffusion, dielectric capping and laser annealing have been developed to increase the intermixing rate of quantum wells in selected regions of a wafer. In this way, wavelengths of the emitted coherent electromagnetic radiation can be adjusted within the process parameters in the semiconductor laser.

The proposed principle can be applied to different types of semiconductor lasers. According to at least one embodiment, the semiconductor layer sequence is designed as a distributed feedback laser, as an edge-emitting laser or as a horizontal cavity surface-emitting laser.

According to at least one embodiment, the semiconductor laser comprises a radiation outcoupling surface comprising a first subregion and a second subregion different from the first subregion. The coherent electromagnetic radiation of the first wavelength is emitted from the first subregion along a radiation direction. The coherent electromagnetic radiation of the second wavelength is emitted from the second subregion along the same radiation direction.

The radiation outcoupling surface defines the radiation direction of the semiconductor laser. This is set, for example by the semiconductor layer sequence, so that the coherent electromagnetic radiation of the different wavelengths can be emitted along the same direction. This allows the semiconductor laser to be used as a single component and simplifies alignment in relation to the other components of the optical sensor arrangement.

According to at least one embodiment, the radiation outcoupling surface comprises one or more further subregions different from the first and second subregions. The coherent electromagnetic radiation emitted from active regions of further active layers is emitted from the further subregions along the same radiation direction. The emission along the common radiation direction can be generalized in the sense that the coherent electromagnetic radiation of the different wavelengths can be emitted along the same radiation direction.

According to at least one embodiment, the emitter unit comprises a driver circuit for operating the semiconductor laser. The driver circuit is configured to control the semiconductor laser such that the coherent electromagnetic radiation of one of the emitted wavelengths is emitted with a time offset to the coherent electromagnetic radiation of at least one other emitted wavelength.

For example, the driver circuit can drive the semiconductor laser in such a way that it emits the coherent electromagnetic radiation in the form of laser pulses. In this way, a first pulse corresponding to the first wavelength is followed with a time offset by a second pulse corresponding to the second wavelength. The pulse sequence can be generalized as desired to the number of wavelengths used. As the pulses can be detected wavelength-selectively by the optical sensor, the pulses can follow each other in quicker succession with the time offset. This is advantageous for LiDAR systems, for example, where the minimum time between two successive pulses is essentially limited by distance and time-of-flight.

According to at least one embodiment, the receiver unit comprises a measuring circuit. The measuring circuit is configured to read out electromagnetic radiation detected by the optical sensor as sensor signals. The sensor signals can be assigned to one of the wavelengths of the emitted coherent electromagnetic radiation by the measuring circuit depending on the time offset.

During operation, the optical sensor can selectively detect electromagnetic radiation depending on its wavelength. For example, the optical sensor can generate a first sensor signal that indicates electromagnetic radiation of the first wavelength. In addition, the optical sensor can, for example, generate a second sensor signal that indicates electromagnetic radiation of the second wavelength. This can be generalized to all wavelengths used or emittable by the semiconductor laser. For this purpose, the optical sensor can be configured to selectively detect the wavelengths, for example using filters, so that different channels of the sensor provide the respective sensor signals. Another option is to use several optical sensors. For example, a first optical sensor can be configured to detect the first wavelength and a second optical sensor can be configured to detect the second wavelength. This can again be achieved using suitable filters. This can also be generalized to all wavelengths used or emittable by the semiconductor laser, for example by using a corresponding number of sensors. For example, suitable wavelength-selective beam splitters can be used to guide the beam to the individual sensors.

In various applications, it can be advantageous for scattered or reflected electromagnetic laser radiation from a distant target to be directed towards the optical sensor (s) . These applications include scanning LiDAR, flash LiDAR, differential LiDAR, but also time-of-flight, proximity sensing, spectral sensing and others. These applications can particularly benefit from the fact that the semiconductor laser provides a plurality of wavelengths, so that the corresponding measurements can be extended to a certain extent to multi-color.

According to at least one embodiment, the emitter unit comprises a movable mirror. The movable mirror, or scanning mirror, is configured to direct the emitted coherent electromagnetic radiation towards the distant target. Alternatively, or additionally, the movable mirror is configured to direct the emitted coherent electromagnetic radiation across an angular range that defines a field of view. Furthermore, the measuring circuit is configured to assign the sensor signals to a position of the movable mirror.

With the movable mirror, the optical sensor arrangement can be used as a scanning LiDAR system. Due to the different wavelengths of the emitted coherent electromagnetic radiation, the durations of successive pulses can be reduced, for example.

According to at least one embodiment, the measuring circuit is configured to measure a start time of the emission for the emitted coherent electromagnetic radiation. Furthermore, the measuring circuit is configured to measure an end time for electromagnetic radiation detected by the optical sensor. The measuring circuit can generate an output signal from the start and end time, which represents a measure of the distance of the distant target to the optical sensor arrangement.

The difference between the start and end time is a measure of the time-of-flight (TOF) required for a light pulse to reach the distant object and return to the optical sensor arrangement after reflection or scattering. The speed of light can be used to determine a distance from the start and end time. The optical sensor arrangement can thus be used to determine a distance or to record distance-resolved images. The fast pulse sequence presented here can also be an advantage.

According to at least one embodiment, the measuring circuit is configured to generate a differential signal from sensor signals following one another according to the time offset. Different applications can be made possible with the aid of the differential signal based on different wavelengths.

For example, the optical sensor arrangement can be used as a differential LiDAR spectrometer. Differential absorption LiDAR (DIAL) is a laser remote sensing technique that can be used for distance-resolved (profile) measurements of atmospheric gas concentrations. For example, DIAL uses the gas absorption properties in two wavelengths and therefore requires a multi-color laser to generate a peak of an absorption line of the gas of interest and a second wavelength in a region of low absorption. The differential signal generated by the optical sensor device, or the individual sensor signals, can be used for DIAL measurements. In addition, other aspects of other embodiments can be used in a complementary manner, for example to combine the differential signal with distance information.

It can also be advantageous to use different sensor signals corresponding to the different wavelengths in order to evaluate additional information about the environment of the optical sensor arrangement and, if necessary, to take it into account for a measurement.

For example, lasers in a LiDAR system should overcome the ambient light, usually dominated by sunlight, in order to make obstacles detectable. For this reason, operating wavelengths are often selected in regions with a low solar flux index in order to detect less sunlight. For example, a plot of solar photon flux versus ground wavelength (the amount of sunlight hitting the earth versus wavelength) shows that at 850 nm there is almost 2x more sunlight than at 905 nm, up to 10x more sunlight than at 940 nm and up to 3x more sunlight than at 1550 nm. By tuning the design of the semiconductor laser to such emission wavelengths, it is possible to specifically emit light for which the relative intensities are known from the solar photon flux. A differential signal as introduced above can then serve as a measure of the ambient light and, for example, compensate for the measurement signals of the optical sensor arrangement. It should be noted, for example, that the achievable emission wavelengths are up to approx. 50 nm apart due to quantum well intermixing.

It can also be advantageous to adjust the emission wavelength to the following circumstances. Water vapor in the upper atmosphere absorbs in the solar spectrum at 905, 940 and 1550 nm. However, this absorption also occurs in humid and foggy conditions on the ground when laser pulses are transmitted through the air. As a result, the optical sensor detects less laser light. In contrast, the 850 nm spectrum generally has lower absorption of atmospheric water vapor, in particular several orders of magnitude better than other operating wavelengths such as 1550 nm. Using the semiconductor laser, humid conditions can be estimated by comparing sensor signals at the different wavelengths.

According to at least one embodiment, the semiconductor laser is implemented on a chip. The semiconductor laser can be implemented as a single component, which facilitates optical alignment, for example. The optical sensor arrangement can thus be made more compact and robust.

According to at least one embodiment, the emitter unit and the receiver unit are arranged in a common housing or in a common module in relation to each other. The optical sensor arrangement can be realized particularly compactly in a housing or even in a sensor module, for example as a flash LiDAR system.

Further advantages and advantageous embodiments as well as further developments of the presented description will become apparent from the embodiments described below in conjunction with figures.

In the exemplary embodiments and figures, components that are identical or have the same effect may each be provided with the same reference signs. The elements shown and their size ratios to one another are not generally to be regarded as true to scale; rather, individual elements, such as layers, components, structural elements and regions, may be shown with exaggerated thickness or large dimensions for better visualization and/or better understanding.

### BRIEF DESCRIPTION OF THE DRAWINGS

In the figures:

FIG. 1 shows an exemplary embodiment of an optical sensor arrangement,

FIG. 2 shows an exemplary embodiment of a semiconductor laser,

FIG. 3 shows a further exemplary embodiment of a semiconductor laser,

FIG. 4 shows a further exemplary embodiment of a semiconductor laser,

FIG. 5 shows an exemplary embodiment of a quantum well intermixing method,

FIG. 6 shows an exemplary embodiment of the quantum well intermixing method,

FIG. 7 shows an exemplary embodiment of the quantum well intermixing method, and

FIG. 8 shows a further exemplary embodiment of a semiconductor laser.

### DETAILED DESCRIPTION

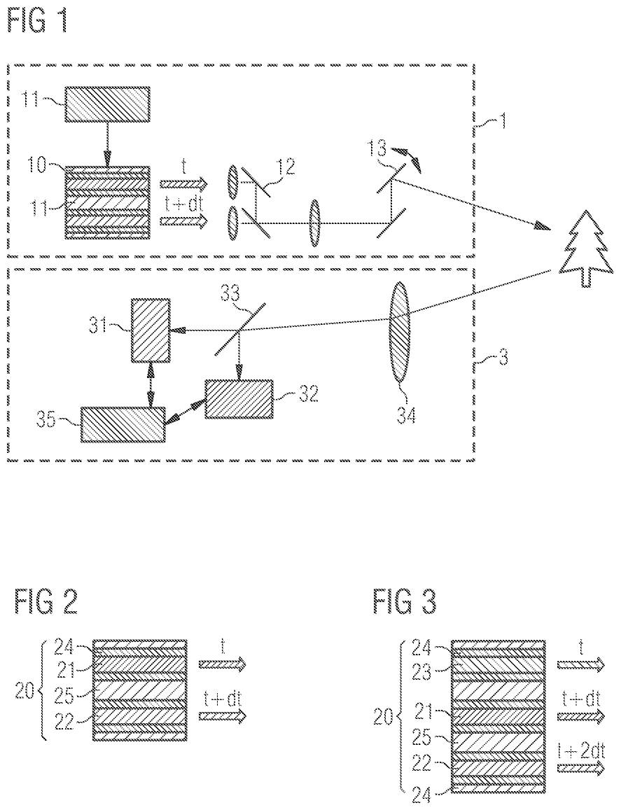

FIG. 1 shows an exemplary embodiment of an optical sensor arrangement. This sensor arrangement can be used, for example, for a scanning LiDAR system. LiDAR (abbreviation for light detection and ranging or light imaging, detection and ranging) enables optical distance and speed measurement as well as remote measurement of atmospheric parameters. The concept presented here can be used for various LiDAR systems. An example of multidimensional laser scanning LiDAR is shown below.

The components of the optical sensor arrangement are arranged in a common housing. The sensor arrangement comprises an emitter unit 1 and a receiver unit 3. The emitter unit and the receiver unit are optically separated or isolated from each other, for example in two halves of a housing or separated by an optical barrier. The housing is also used to align and adjust the components of the optical sensor arrangement with respect to each other or to optically separate them from each other in order to prevent crosstalk.

The emitter unit 1 comprises a semiconductor laser. The semiconductor laser comprises a semiconductor layer sequence 20 with a substrate on which a plurality of functional, epitaxially grown layers are applied. Thus, the semiconductor laser comprises a plurality of active layers with active regions that can emit coherent electromagnetic radiation during operation. In this example, the semiconductor laser comprises two active regions, each of which is arranged in an active layer. This number is to be understood as an example and serves only as a simplified illustration. Depending on the application, any other number of active regions may be present. The active layers are based on the same semiconductor layer sequence. However, the active layers comprise mixed quantum well structures produced by a quantum well intermixing method.

During operation, the active regions emit coherent electromagnetic radiation of different wavelengths. This can be achieved using mixed quantum well structures, as will be explained below. In this example with two active regions, the semiconductor laser can emit two wavelengths. The two wavelengths are different and separated from each other by at least one half-width. Preferably, the two wavelengths are separated by at least 5 nm or more than 10 nm. The measure that can be used here is how selectively optical sensors 31, 32 also present in the optical sensor arrangement can detect.

The emitter unit 1 comprises an optical beam guidance arrangement 12 and a scanning mirror 13. The optical beam guiding arrangement is arranged relative to the semiconductor laser 10 such that a beam of the first wavelength and another beam of the second wavelength are deflected onto a common optical axis. The optical axis is directed towards the scanning mirror so that both beams can be aligned with the mirror. In this way, the semiconductor laser, which as a single component or light source emits beams of different wavelengths, is directed towards the scanning mirror. The scanning mirror can be rotated and can be continuously aligned during operation of the sensor arrangement so that the emitted electromagnetic radiation is directed onto a distant target 5. In this way, the semiconductor laser emits light of the first and/or second wavelength in the direction of the distant target, which can then scatter or reflect the light. Part of the scattered or reflected light can be received again at the receiver unit 3.

The receiver unit 3 comprises at least one optical sensor. In this example, two optical sensors 31, 32 are arranged in the receiver unit. The optical sensors are of the same type, for example. Typically, single or multiple photodiodes, such as single-photon avalanche diodes (SPAD for short), are used. The optical sensors can selectively detect electromagnetic radiation according to the first and second wavelengths. For example, the first optical sensor 31 is equipped with a first filter having a bandpass for the first wavelength. Accordingly, the second optical sensor 32 can comprise a second filter with a bandpass for the second wavelength. Preferably, the two bands of the filters are selected such that they have no spectral overlap, i.e. the respective other of the two wavelengths is not transmitted or has a transmission of close to or equal to zero.

Alternatively, or additionaly, a wavelength-selective beam splitter 33 can be provided in the emitter unit, which splits an incident beam into portions of the first or second wavelength. In this way, only light of the first wavelength is directed towards the first optical sensor 31 or light of the second wavelength is directed towards the second optical sensor 32. A combination of filters and beam splitter can increase selectivity and reduce optical crosstalk. The receiver unit also comprises a receiver optics unit 34, which initially directs light scattered or reflected by the distant target 5 onto the beam splitter 33 and thus onto the optical sensors 31, 32.

The optical sensor arrangement also includes electronic components to implement operation as a LiDAR system. For example, the emitter unit 1 comprises a driver circuit 11 for operating the semiconductor laser and the receiver unit 3 comprises a measurement circuit 35.

The driver circuit 11 controls the semiconductor laser 10 and thus determines when which of the two implemented wavelengths is emitted. For example, the semiconductor laser can be used in a pulsed mode, where pulses of the different wavelengths are emitted with a time offset. The time offset dt can be set by means of the driver circuit.

The measuring circuit 35 reads out the electromagnetic radiation detected by the optical sensor in the form of sensor signals. The measuring circuit is synchronized with the driver circuit 11 in such a way that the sensor signals are each assigned to one of the wavelengths of the emitted coherent electromagnetic radiation by the measuring circuit 35. For example, the measuring circuit determines a start time when a pulse is emitted and an end time when the corresponding pulse is detected wavelength-selectively by one of the optical sensors 31, 32. Due to the time offset and the different wavelength of successive pulses, the detection can therefore be unambiguous. In addition, the measuring circuit can generate an output signal from the determined start and stop times, which can represent a measure of the time-of-flight of the pulses and thus of the distance to a distant target. Together with the rotational position of the scanning mirror 13, a multi-dimensional image with distance information can be generated.

In a further embodiment not shown, a receiver path can also be realized via the scanning mirror, which reduces the detector size and ambient light on the optical sensor, but makes the optics more complex. In this case, the field of view of the receiver unit 3 should be larger than the transmission field of the emitter unit 1.

In a further embodiment not shown, a transmitter path can be designed without a beam combination, whereby the emission of the two different wavelengths, for example, takes place in at least slightly different spatial directions. If the optics of the receiver path are designed with sufficient tolerance so that both spatial directions are detected, or if the two optical sensors designed for the respective wavelength (e.g. comprising a filter) have an approximately identical offset in the acceptance angle as the angle between the emission directions of the two lasers, this arrangement enables the simultaneous emission of both wavelengths and thus parallel distance measurement in two spatial directions. The use of two wavelengths is particularly advantageous when the beam angles are close together, as it is difficult to completely separate the reception regions of the sensors optically in this case. This can also double the overall resolution of the sensor arrangement.

FIG. 2 shows an exemplary embodiment of a semiconductor laser. The schematic representation shows the laser 10 with a semiconductor layer sequence 20 in plan view. Shown as strips are a first active layer 21 and a second active layer 22, each comprising quantum well structures as active regions. The semiconductor layer sequence is processed by a quantum well intermixing method, so that the first active layer emits a first wavelength and the second active layer emits a second wavelength of coherent electromagnetic radiation, for example in the form of pulses. The quantum well mixture is influenced by the material thickness of a cover layer 24, for example made of Si02. The respective emission wavelength can be set during the manufacturing process by selecting the appropriate material thickness. The individual strips are separated from each other by a separating layer 25.

The two active layers 21, 22 can be controlled by the driver circuit 11 sequentially or separately one after the other according to a time offset dt. The time offset dt can be set to dt=2·dmax/2·c at a maximum distance dmax, where c is the speed of light. In conventional scanning or flash LiDAR systems, only a time offset of dt=2·dmax/c is possible with only one wavelength per laser. In other words, a factor of 2 can be achieved using one of the proposed semiconductor lasers with two wavelengths. With the improved time offset, it is not necessary to wait for the backscattering or reflection of an emitted pulse to be detected before the next pulse can follow. Instead, a pulse of the second or one of the other wavelengths of the semiconductor laser can be emitted even before a returning pulse of the first wavelength has been detected. The only requirement is an optical sensor that can selectively detect the two wavelengths or a corresponding number of optical sensors, each of which is sensitive to one of the wavelengths used.

FIG. 3 shows a further exemplary embodiment of a semiconductor laser. The schematic representation also shows the laser with a semiconductor layer sequence 20 in plan view. A first, a second and a third active layer 21, 22, 23 are shown as strips, each comprising quantum well structures as active regions. The semiconductor layer sequence is processed by a quantum well intermixing method, so that the first active layer 21 emits a first wavelength, the second active layer 22 emits a second wavelength and the third active layer 23 emits a third wavelength of coherent electromagnetic radiation, for example in the form of pulses. The quantum well mixture is influenced by the material thickness of a cover layer 24, for example made of Si02. The respective emission wavelength can be set during the manufacturing process by selecting the appropriate material thickness. The individual strips are separated from each other by a separating layer 25.

The three active layers can be controlled by the driver circuit sequentially or separately one after the other according to the time offset dt. The time offset dt can be set to dt=2·dmax/3·c at a maximum distance dmax, where c is the speed of light. This means that a factor of 3 can be achieved with three wavelengths compared to prior art solutions. The only requirement is an optical sensor that can selectively detect the three wavelengths or a corresponding number of optical sensors, each of which is sensitive to one of the wavelengths used.

Based on the assumption that the temperature drift is around ˜0.3 nm/K (as in edge-emitting lasers, for example) and the technological limits that apply, semiconductor lasers with 2 to 3 wavelengths are possible for LiDAR applications, provided that no active temperature stabilization is implemented in the LiDAR system or the optical sensor arrangement. With such active temperature stabilization, more than three wavelengths, for example 5 to 6 wavelengths, can also be useful for LiDAR. In general, n wavelengths are possible and the time offset can be further reduced to dt=2·dmax/n·c.

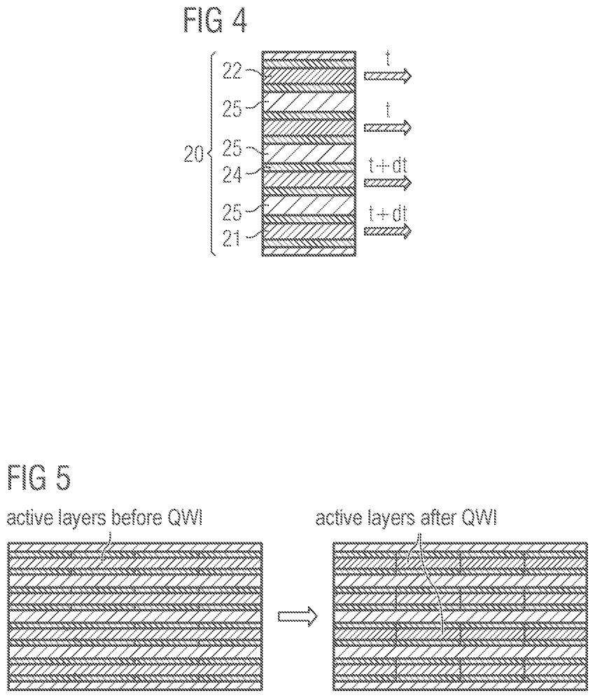

FIG. 4 shows a further exemplary embodiment of a semiconductor laser. The schematic representation also shows the laser 10 with a semiconductor layer sequence 20 in plan view. Two strips of a first active layer 21 and two strips of a second active layer 22 are shown, each comprising quantum well structures as active regions. The semiconductor layer sequence is processed by a quantum well intermixing method, so that the first active layers emit a first wavelength and the second active layers emit a second wavelength of coherent electromagnetic radiation, each in the form of a pulse. The quantum well mixture is influenced by the material thickness of a cover layer 24, for example made of Si02. The respective emission wavelength can be set during the manufacturing process by selecting the appropriate material thickness. The individual strips are separated from each other by a separating layer 25.

Such a semiconductor layer sequence can be implemented, for example, if more power per wavelength is required. The active layers of the same wavelength or channels of the same color can be connected in parallel (for example by increasing the current) and thus be controlled jointly by the driver circuit. Different colors are operated separately and at different times, as already described in connection with the other embodiments. Only the beam guidance optics can be optimized, for example to ensure dark-spot-free far-field projection.

FIG. 5 shows an exemplary embodiment of a quantum well intermixing method. The example is aimed at two wavelengths in two channels. The schematic representation shows the laser with a semiconductor layer sequence 20 in plan view before (left) and after the process (right). QWI is an integration technology in which properties of quantum well structure can be modified after growth. Intermixing the potential wells and barriers of quantum well structures generally leads to an increase in the band gap and is accompanied by changes in the refractive index.

A semiconductor layer sequence 20 is applied to a wafer or substrate, the layers of said semiconductor layer sequence representing a plurality of functional, epitaxially grown layers. The drawing shows a strip of a first active layer 21 and a second active layer 22, each with a quantum well structure as the active region. The quantum well mixture is characterized by the material thickness of a cover layer, for example made of SiO₂. In the manufacturing process, the material thickness of this layer determines the emission wavelength of the respective quantum well structure and thus the possible emission wavelength in laser operation. The individual strips are separated from each other by a separating layer 25. A possible semiconductor layer sequence is published in IEEE Journal of the Electron Devices Society (Volume: 5, Issue: 2, March 2017) . The content of this publication is incorporated by reference into this description. In the exemplary embodiment shown, the semiconductor layer sequence forms a quantum well intermixing structure based on an InGaAs/GaAs/AlGaAs quantum well QW complete structure in the infrared wavelength range from a single chip with SiO₂ in simple stoichiometry as the cover layer 24.

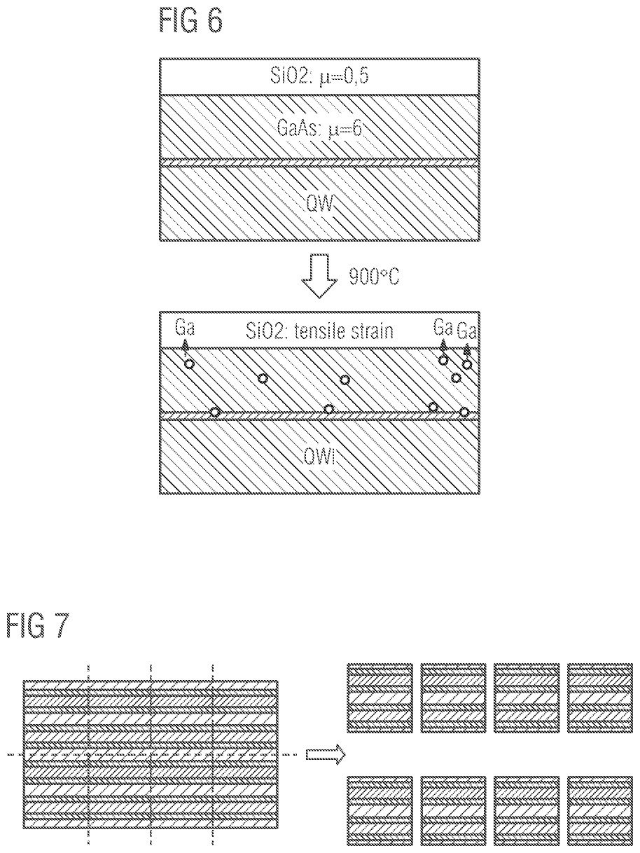

FIG. 6 shows an exemplary embodiment of the quantum well intermixing method. This example shows a possible process that can be used to manufacture a semiconductor laser for the optical sensor arrangement. For impurity-free QWI, for example, a cover layer of Si0₂ is deposited on an epitaxially grown GaAs surface of the laser. A quantum well structure is arranged in this layer. In the drawing, the thermal expansion coefficients μ are given in units of μm/° K.

By annealing at a suitably high temperature, for example 900° C., the resulting strain causes Ga atoms (shown as white dots) to leave the GaAs surface layer and penetrate into the dielectric layer or the cover layer. The remaining point defects diffuse into the semiconductor and lead to an exchange of positions of the atoms past which the point defects diffuse. This material exchange causes the atoms of the quantum wells and the barriers to mix, which leads to an increase in the band gap and thus to a change in the emission wavelength. It was found that the degree of intermixing can be controlled by varying the thickness of the Si02 layer, making it possible to process lasers with different wavelengths on one chip.

It should be noted in this method that QWI works with single-stack epis. Instead of gaining power from a multi-stack, this can be compensated for by enlarging the active region, e.g. by using longer resonators. Several channels (even with the same wavelength) can be combined.

FIG. 7 shows an exemplary embodiment of the quantum well intermixing method. The wafer with the semiconductor layer sequence resulting from the method of FIG. 6 can be separated into individual semiconductor lasers in a further step. In this way, a large number of semiconductor lasers can be produced on one wafer.

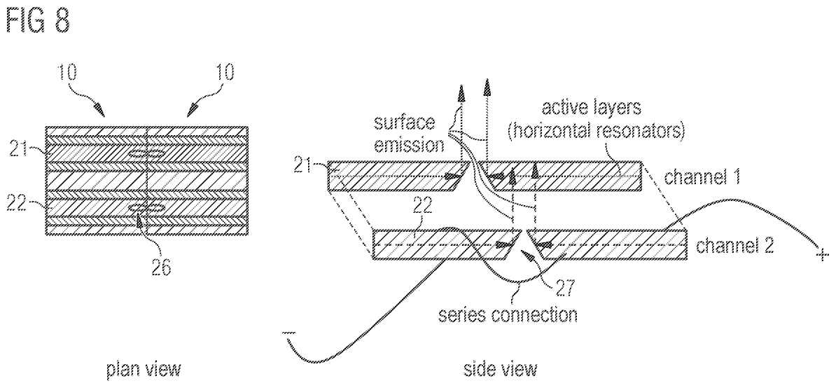

FIG. 8 shows another exemplary embodiment of a semiconductor laser. It was described above how individual active layers or channels can be combined to increase the output power of the semiconductor laser. This is a suitable solution for edge-emitting lasers, for example. For other laser types, implementations are also possible that enable increased output power with a higher voltage instead of an increased current.

One example is the horizontal cavity surface-emitting laser, HCSEL. Quantum well intermixing is also possible with this type according to the concept presented above. However, two semiconductor lasers 10 with the same wavelengths can be achieved, for example, each emitting the two wavelengths from the respective active layers, which are shown next to each other at the same height in the drawing (see left-hand side of the drawing, plan view) . The emission regions 26 are shown as ellipses. In this way, twice the power over the same spot and the same current is possible if the two semiconductor lasers are connected in series and controlled by the driver circuit (such as, for example, an unfolded two-part edge-emitting laser). Series connection is possible, for example, using a lift-off method, which is not possible with standard edge-emitting lasers. Different wavelength channels can in turn be operated separately.

The right-hand side of the drawing shows a side view of the active regions or quantum well structures of the HCSEL. Two channels corresponding to a first and second emission wavelength of two HCSELs in series are shown. The series connection is indicated by a sinusoidal voltage curve. The active layers are designed as horizontal resonators and each have an etched prism structure at their opposite ends. In this way, the emission of the HCSEL can be coupled out as surface emission from both lasers in a common radiation direction. The concept of series connection of HCSELs and joint outcoupling via prism structures can be generalized to more than two lasers by coupling two adjacent lasers in series as described above.

The foregoing description explains many features in specific detail. These are not intended to be construed as limitations on the scope of the improved concept or what can be claimed, but rather as exemplary descriptions of features that are specific only to certain embodiments of the improved concept. Certain features described in this description in connection with individual embodiments may also be realized in combination in a single embodiment. Conversely, various features described in connection with a single embodiment may also be implemented in multiple embodiments separately or in any suitable sub-combination. Moreover, although features are described above as acting together in certain combinations and even originally claimed as such, one or more features from a claimed combination may in some cases be excluded from the combination, and the claimed combination may be directed to a sub-combination or variation of a sub-combination.

Although the drawings show operations in a particular order, this is not to be taken to mean that these operations must be carried out in the order shown or in sequential order, or that all the operations shown must be carried out to achieve the desired results. In certain circumstances, different sequences or parallel processing may be advantageous.

A number of implementations have been described. Nevertheless, various modifications can be made without departing from the spirit and scope of the improved concept. Accordingly, other implementations also fall within the scope of the claims.

1. An optical sensor arrangement comprising an emitter unit and a receiver unit; wherein:
the emitter unit comprises a semiconductor laser configured to emit coherent electromagnetic radiation having at least two wavelengths, and
the emitter unit is configured to direct the emitted electromagnetic radiation towards a distant target; wherein
the receiver unit comprises at least one optical sensor configured to selectively detect electromagnetic radiation depending on the at least two wavelengths, and
the receiver unit is arranged relative to the emitter unit and configured such that electromagnetic radiation scattered or reflected by the distant target is detectable on the optical sensor.

2. The optical sensor arrangement according to claim 1, wherein
the semiconductor laser comprises a semiconductor layer sequence comprising at least a first active layer and a second active layer,
the first active layer comprises one or more first active regions each formed as a quantum well structure, the quantum well structure being configured to emit coherent electromagnetic radiation having a first wavelength, and
the second active layer comprises one or more second active regions each formed as a quantum well structure, the quantum well structure being configured to emit coherent electromagnetic radiation having a second wavelength.

3. The optical sensor arrangement according to claim 2, wherein
the semiconductor layer sequence comprises one or more further active layers comprising active regions formed as a quantum well structure, and
the quantum well structure is configured in each case to emit coherent electromagnetic radiation having a further wavelength.

4. The optical sensor arrangement according to claim 3, wherein the further wavelength or wavelengths are different from the first and second wavelengths or correspond to one of the other wavelengths.

5. The optical sensor arrangement according to claims 2, wherein one or more of the active layers have a mixed quantum well structure, or quantum well intermixing, as the quantum well structure.

6. The optical sensor arrangement according to claims, wherein the semiconductor layer sequence is designed as a distributed feedback laser, as an edge-emitting laser or as a horizontal cavity surface-emitting laser.

7. The optical sensor arrangement according to any one of claims claim 2, wherein
the semiconductor laser comprises a radiation outcoupling surface comprising a first subregion and a second subregion different from the first subregion,
the coherent electromagnetic radiation having the first wavelength is emitted from the first subregion along a radiation direction, and
the coherent electromagnetic radiation having the second wavelength is emitted from the second subregion along the same radiation direction.

8. The optical sensor arrangement according to claim 7, wherein:
the radiation outcoupling surface comprises one or more further subregions different from the first and second subregions, and
the coherent electromagnetic radiation emitted from active regions of further active layers is emitted from the further subregions along the radiation direction.

9. The optical sensor arrangement according to claim 1, wherein:
the emitter unit comprises a driver circuit for operating the semiconductor laser, and
the driver circuit is configured to control the semiconductor laser such that the coherent electromagnetic radiation of one of the emitted wavelengths is emitted with a time offset to the coherent electromagnetic radiation of at least one other emitted wavelength.

10. The optical sensor arrangement according to claim 9, wherein:
the receiver unit comprises a measuring circuit,
the measuring circuit is configured to read out electromagnetic radiation detected by the optical sensor as sensor signals and to assign the sensor signals to one of the wavelengths of the emitted coherent electromagnetic radiation depending on the time offset.

11. The optical sensor arrangement according to claim 10, wherein:
the emitter unit comprises a movable mirror configured to direct the emitted coherent electromagnetic radiation towards the distant target, or configured to direct the emitted coherent electromagnetic radiation across an angular range defining a field of view,
the measuring circuit is configured to assign the sensor signals to a position of the movable mirror.

12. The optical sensor arrangement according to claim 10, wherein:
the measuring circuit is configured to measure a start time of the emission for the emitted coherent electromagnetic radiation,
the measuring circuit is configured to measure an end time for electromagnetic radiation detected by the optical sensor, and
to generate an output signal from the start and end time, which represents a measure of the distance of the distant target to the optical sensor arrangement.

13. The optical sensor arrangement according to claim 10, wherein the measuring circuit is configured to generate a differential signal from sensor signals following one another according to the time offset.

14. The optical sensor arrangement according to claim 1, wherein the semiconductor laser is implemented on a chip.

15. The optical sensor arrangement according to claim 1, wherein the emitter unit and the receiver unit are arranged in a common housing or module in relation to each other.

16. An optical sensor arrangement comprising an emitter unit and a receiver unit;
wherein:
the emitter unit comprises a semiconductor laser configured to emit coherent electromagnetic radiation having at least two wavelengths,
the emitter unit comprises a driver circuit for operating the semiconductor laser, and
the driver circuit is configured to control the semiconductor laser such that the coherent electromagnetic radiation of one of the emitted wavelengths is emitted with a time offset to the coherent electromagnetic radiation of at least one other emitted wavelength, and
the emitter unit is configured to direct the emitted electromagnetic radiation towards a distant target;
wherein
the receiver unit comprises at least one optical sensor configured to selectively detect electromagnetic radiation depending on the at least two wavelengths, and
the receiver unit is arranged relative to the emitter unit and configured such that electromagnetic radiation scattered or reflected by the distant target is detectable on the optical sensor.
